(19) United States
(12) Patent Application Publication
(10) Pub. No.: US 2016/0155658 A1
(43) Pub. Date: Jun. 2, 2016

(54) SEMICONDUCTOR WAFER HOLDER AND WAFER CARRYING TOOL USING THE SAME

(71) Applicant: MACRONIX International Co., Ltd., Hsinchu (TW)

(72) Inventor: Chin-Cheng Yang, Hsinchu (TW)

(21) Appl. No.: 14/558,267

(22) Filed: Dec. 2, 2014

(51) Int. Cl. H01L 21/687; B25J 15/00

(52) U.S. Cl. CPC H01L 21/68742; B25J 15/009

(57) ABSTRACT

A wafer holder and a semiconductor wafer carrying tool including the wafer holder are provided. The wafer holder includes a frame portion, a wafer centering unit and a plurality of support pins for supporting the wafer carried by the wafer holder. The wafer centering unit comprises a plurality of pin cassettes, and the plurality of pin cassettes is arranged on the frame portion in diagonal positions. Each of the plurality of pin cassettes individually includes a retractable pin, and the retractable pins can be protruded out of the pin cassettes to function together as a space limiting tool to force the carried wafer to calibrate its position.

### BACKGROUND OF THE INVENTION

1. Field of the Invention

The present invention generally relates to a semiconductor wafer carrying means, in particular, to a semiconductor wafer carrying tool with improved positioning accuracy.

2. Description of Related Art

One essential part of the semiconductor manufacture involves sequential processing in a cluster tool platform with different chambers. For cluster-tool processing, the wafer may be transferred among different chambers to be processed. Except for the buffer and wafer idling commonly seen in the sequential processing, the efficiency of the wafer transferring process and the positioning accuracy of the transferred wafer have to be carefully taken into consideration.

### SUMMARY OF THE INVENTION

The present invention provides a wafer holder and a semiconductor wafer carrying tool including the wafer holder are provided. By using the wafer holder having a wafer centering unit, the position of the wafer held by the wafer holder is calibrated to avoid possible position deviation.

The present invention provides a wafer holder for carrying a wafer. The wafer holder includes a frame portion, a wafer centering unit and a plurality of support pins for supporting the wafer carried by the wafer holder. The wafer centering unit comprises a plurality of pin cassettes, and the plurality of pin cassettes is arranged on the frame portion in diagonal positions. Each of the plurality of pin cassettes individually includes a retractable pin. The plurality of support pins arranged on the frame portion in diagonal positions is separate from the plurality of pin cassettes.

The present invention provides a semiconductor wafer carrying tool structure. The wafer carrying tool structure comprises a support body, a first shaft, an anti portion, a second shaft and a wafer holder. The first shaft is connected with the support body, and the an n portion is connected with the first shaft. One end of the arm portion is rotatably mounted to the support body through the first shaft. The second shaft is connected with the arm portion, and the wafer holder connected with the second shaft is rotatably mounted on the other end of the arm portion through the second shaft. The wafer holder has a wafer centering unit comprising a plurality of pin cassettes and the plurality of pin cassettes is arranged on a frame portion of the wafer holder in diagonal positions. Each of the plurality of pin cassettes individually includes a retractable pin.

In order to make the aforementioned and other features and advantages of the invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a three-dimensional view of a semiconductor wafer carrying tool according to one embodiment of the present invention.

FIG. 1B is a top view of a semiconductor wafer carrying tool according to one embodiment of the present invention.

FIG. 1C is a cross-sectional view of the semiconductor wafer carrying tool of FIG. 1B.

FIG. 1D is a cross-sectional view of the semiconductor wafer carrying tool of FIG. 1B.

FIG. 2 is a side view of a semiconductor wafer carrying tool according to one embodiment of the present invention.

FIGS. 3A-3F are schematic views illustrating the positioning mechanism of the carried wafer by the wafer centering unit of the wafer carrying tool according to one embodiment of the present invention.

FIG. 4 is a flow chart showing the process steps including the wafer centering step according to one embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts. In the following embodiment, a circuit trace part of a portable device is described as an example for illustration. It is not intended to limit the method or the part structure by the exemplary embodiments described herein.

The present invention describes the semiconductor wafer carrying tool with improved positioning accuracy by using a wafer centering unit to align the center of the wafer with the center of the wafer table.

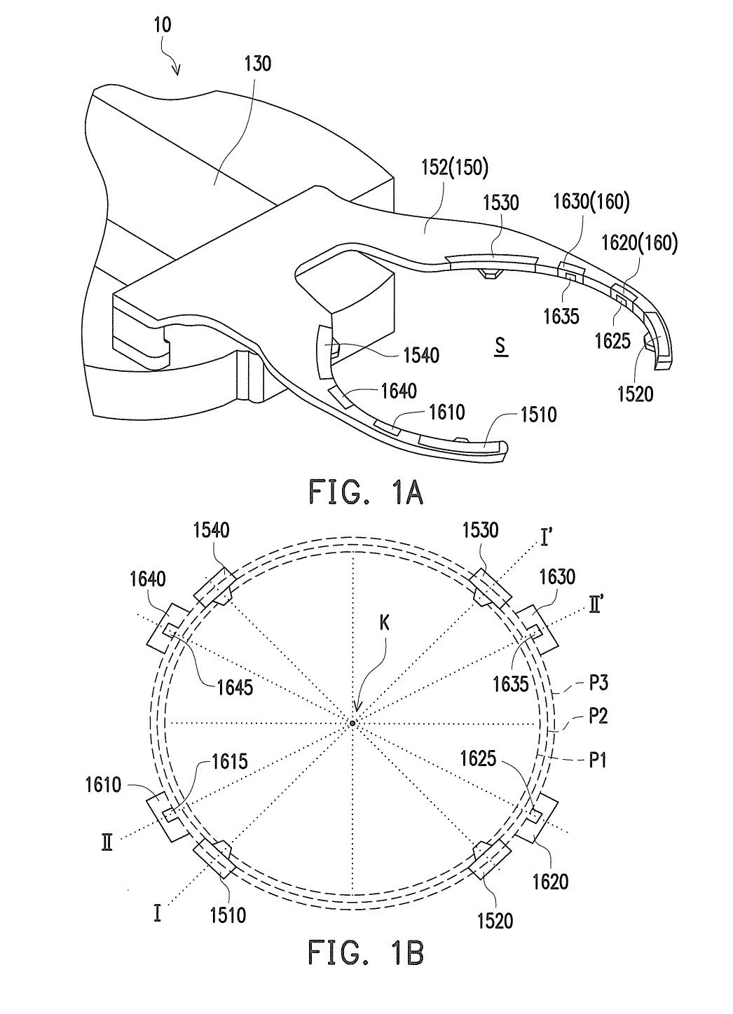

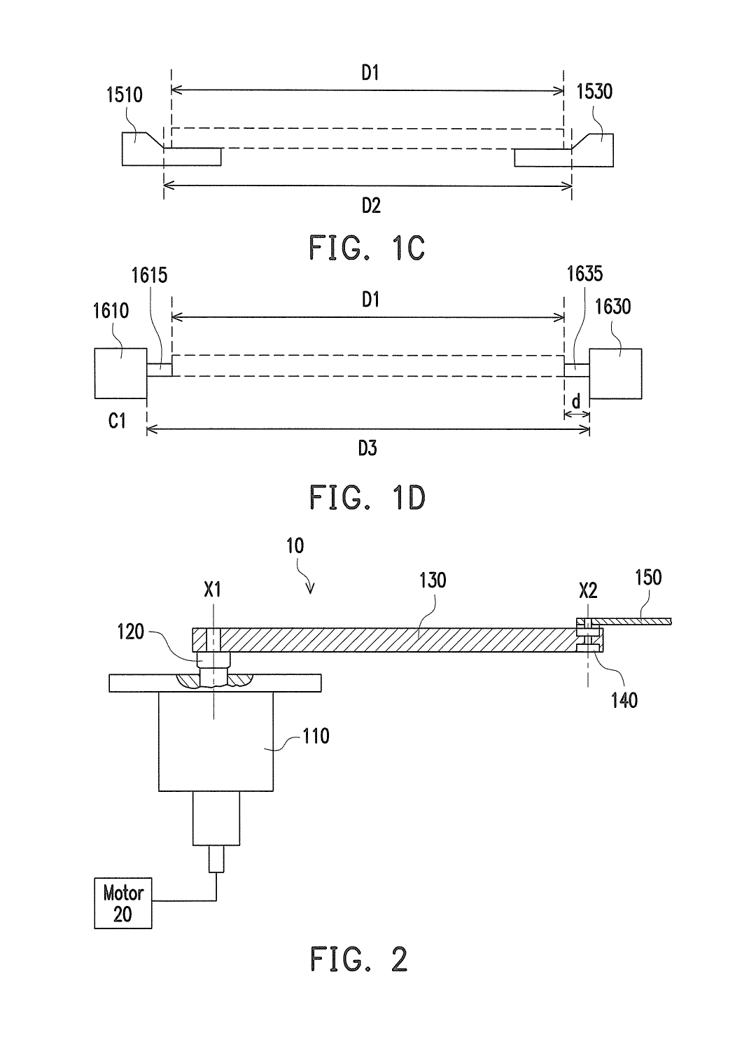

FIG. 1A is a three-dimensional view of a semiconductor wafer carrying tool according to one embodiment of the present invention. FIG. 1B is a top view of a semiconductor wafer carrying tool according to one embodiment of the present invention. FIG. 1C is a cross-sectional view of the semiconductor wafer carrying tool of FIG. 1B. FIG. 1C is a cross-sectional view of the semiconductor wafer carrying tool of FIG. 1B along the section line I-I′. FIG. 1D is a cross-sectional view of the semiconductor wafer carrying tool of FIG. 1B along the section line FIG. 2 is a side view of a semiconductor wafer carrying tool according to one embodiment of the present invention.

In FIGS. 1A-1B & 2, the semiconductor wafer carrying tool 10 includes a support body 110, a first shaft 120, an arm portion 130, a second shaft 140 and a wafer holder 150. The frame portion 152 of the wafer holder 150 is designed to be in a fork shape with two fork ends and principally circular, and the frame portion 152 defines an inner spacing S large enough to accommodate the wafer(s) to be carried. The wafer holder 150 further includes four support pins 1510, 1520, 1530, 1540, arranged on the frame portion 152 and each separate from one another, for supporting and carrying the wafer. Preferably, the support pins 1510, 1530 are arranged in diagonal positions (two opposite end positions along the diameter of the circle), while the support pins 1520, 1540 are arranged in diagonal positions. The wafer holder 150 also includes a wafer centering unit 160, while the wafer centering unit 160 includes four pin cassettes 1610, 1620, 1630, 1640, arranged on the frame portion 152 and each separate from one another. Preferably, the pin cassettes 1610, 1630 are arranged in diagonal positions (two opposite end positions along the diameter of the circle), while the pin cassettes 1620, 1640 are arranged in diagonal positions. The pin cassettes 1610, 1620, 1630, 1640 each individually includes a retractable pin 1615, 1625, 1635 or 1645.

Herein, even though four support pins and four pin cassettes are described as exemplary number of the support pins or the pin cassettes, but the number of the support pins or the pin cassettes is not limited thereto and may be 3 or more.

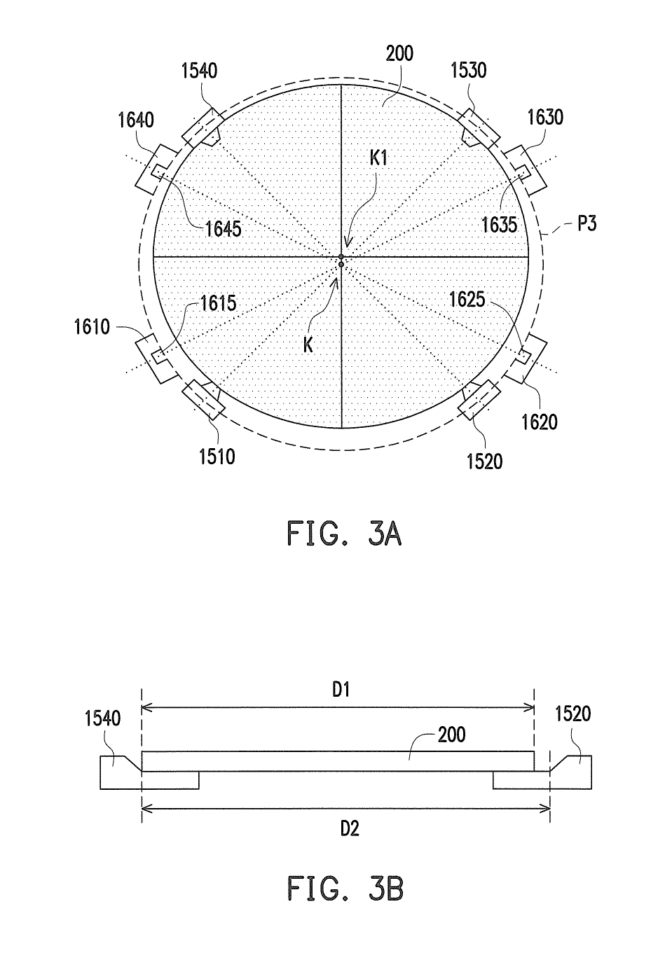

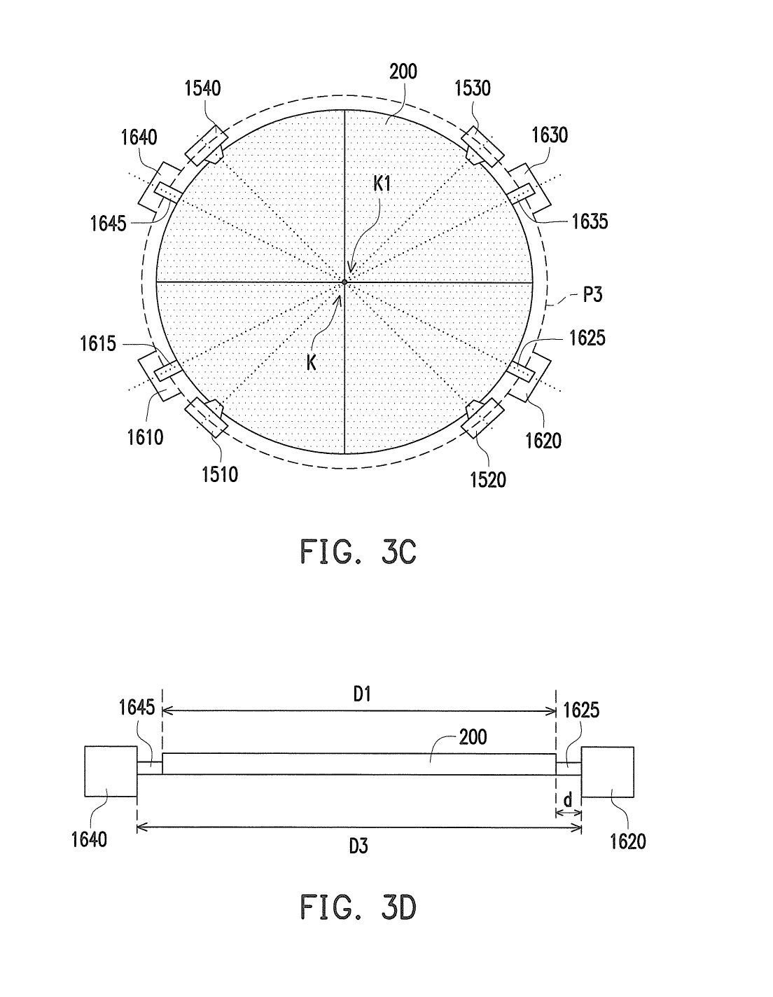

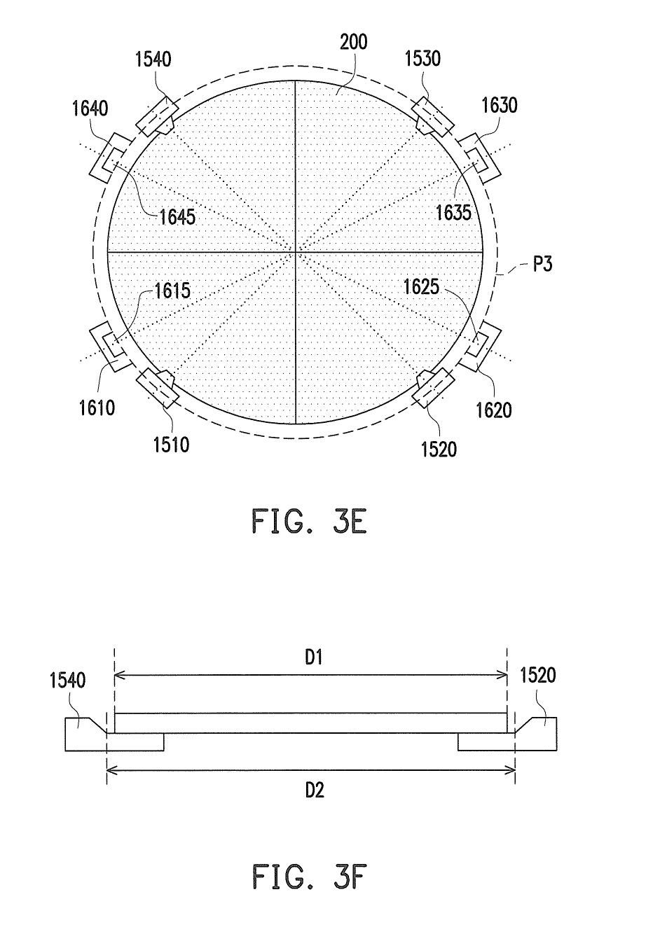

In FIGS. 1B-1D, if considering the wafer to be carried (the carried wafer) has a periphery P1 and a diameter of D1, the periphery P2 of the spacing (with a diameter of D2) defined by the four support pins 1510, 1520, 1530, 1540 arranged separately on the frame portion 152 is located outside of P1 (D2>D1). Similarly, the periphery P3 of the spacing S (with a diameter of D3) defined by the four pin cassettes 1610, 1620, 1630, 1640, arranged on the frame portion 152 is located outside of P1 or P2 (D3>D2>D1). The retractable pins 1615, 1625, 1635, 1645 can be projected or jutted out of the pin cassettes 1610, 1620, 1630, 1640 with a fixed distance d, where d=(D3−D1)/2. That is, when the retractable pins 1615, 1625, 1635, 1645 are jutted out of the pin cassettes 1610, 1620, 1630, 1640 with the fixed distance d, the carried wafer (shown in dotted line in FIG. 1D) will be pushed by the protruded pins 1615, 1625, 1635, 1645 and the position of the carried wafer will be calibrated so that the center K1 of the wafer will be aligned with the center point K of the inner spacing S (as shown in FIG. 3C). When the wafer centering unit 160 is in operation, the retractable pins 1615, 1625, 1635, 1645 should be jutted out of the pin cassettes 1610, 1620, 1630, 1640 at the same time and each pin is protruded with the fixed distance d. The protruded pins 1615, 1625, 1635, 1645 arranged separately on the frame portion 152 together function as a space limiting tool to force the carried wafer to calibrate its position. When the wafer centering unit 160 is not in operation, these retractable pins 1615, 1625, 1635, 1645 are retracted back into and located within the pin cassettes 1610, 1620, 1630, 1640.

As shown in FIG. 2, the semiconductor wafer carrying tool 10 includes a support body 110, a first shaft 120, an aim portion 130, a second shaft 140 and a wafer holder 150. The wafer holder 150 is rotatably mounted on one end of the arm portion 130 by means of the second shaft 140. The other end of the arm portion 130 is rotatably mounted to the support body by means of the first shaft 120. The arm portion 130 rotates about the axis X1 of the first shaft 120, while the wafer holder 150 rotates about the axis X2 of the second shaft 140. Any possible rotary mechanism may be applicable for the first or second shaft. For example, the first shaft 120 may include a drive shaft or a transmission shaft. The support body 110 may be further connected to a motor 20, and the first shaft may be rotated or driven by the motor 20. The second shaft 140 may include a mandrel or a transmission shaft, which may be driven by the motor 20 though the coupling to the support body 110 and/or the motor 20. Alternatively, the second shaft 140 may be independently driven by the motor 20.

FIGS. 3A-3F are schematic views illustrating the positioning mechanism of the carried wafer by the wafer centering unit of the wafer carrying tool according to one embodiment of the present invention. FIGS. 3A, 3C and 3E are schematic top views, while FIGS. 3B, 3D and 3F are cross-sectional views.

In FIGS. 3A-3B, a semiconductor wafer 200 having a diameter D1 and a center point K1 is loaded and carried by the semiconductor wafer carrying tool 10. In FIG. 3A, the position of the carried wafer 200 is shifted so that the center point K1 of the wafer 200 is not coincided with the center point K of the central spacing S (defined by the dotted line and labeled as P3). In fact, the wafer 200 is not disposed exactly at the center but biased toward the support pins 1530, 1540, as shown in FIGS. 3A & 3B. Subsequently, the wafer centering step is performed and the wafer centering unit 160 is in operation, and as shown in FIG. 3C-3D, the retractable pins 1615, 1625, 1635, 1645 are jutted out of the pin cassettes 1610, 1620, 1630, 1640 at the same time and each pin is protruded with the fixed distance d. The protruded pins 1615, 1625, 1635, 1645 together function as a space limiting tool to force the carried wafer 200 to calibrate its position, so that the center point K1 of the wafer 200 is coincided with the center point K of the central spacing S. Afterwards, the wafer centering unit 160 is not in operation, these retractable pins 1615, 1625, 1635, 1645 are retracted back into the pin cassettes 1610, 1620, 1630, 1640, as shown in FIGS. 3E-3F. The carried wafer 200 is disposed exactly at the center of the spacing S defined by the frame portion 152. By using the wafer centering unit 160 (i.e. by performing the wafer centering step), the position of the carried wafer 200 is calibrated and re-adjusted to be located exactly at the predetermined position of the wafer holder 150, and the wafer 200 carried by the wafer holder 150 can be loaded to the prearranged position on the wafer table of the processing chamber or platform, which is essential for the subsequent processing steps. If the wafer carried by the wafer holder is not loaded correctly to the prearranged position on the wafer table (i.e. the wafer is loaded to a shifted position on the wafer table), the biased wafer on the wafer table will not be properly processed in the subsequent processing steps (such as spin coating, immersion, etching or rinsing).

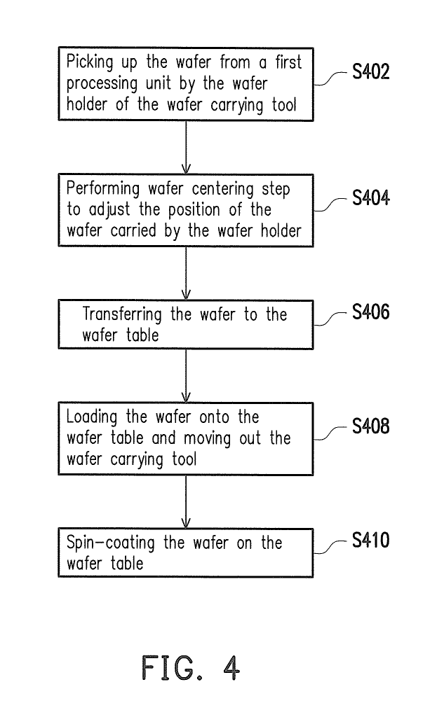

FIG. 4 is a flow chart showing the process steps including the wafer centering step according to one embodiment of the present invention, using the spin coating process as an example. In Step 402 of FIG. 4, the wafer is picked up from a first processing unit by the wafer holder of the wafer carrying tool. In Step 404, the wafer centering step is performed by using the wafer centering unit of the wafer holder to adjust the position of the wafer carried by the wafer holder. During the wafer centering step, the retractable pins are jutted out of the pin cassettes at the same time to force the carried wafer to calibrate its position, so that the so that the carried wafer is disposed exactly at the center of the accommodating spacing of the wafer holder (i.e. the wafer is not off-centered). After the wafer centering step is completed, these retractable pins are retracted back into the pin cassettes (as shown in FIGS. 3C-3F). Through performing the wafer centering step, the position of the carried wafer is calibrated and re-adjusted to be located exactly at the predetermined position of the wafer holder.

In Step 406 of FIG. 4, the calibrated wafer is transferred to a position right above the wafer table of the next process unit. However, it is noted that Steps 404 and 406 may be performed in reverse, i.e. performing Step 406 then Step 404, so that the wafer is transferred to a position right above the wafer table and then performing the wafer centering step. In Step 408, the wafer is loaded onto the prearranged position on the wafer table of the next processing unit, and the wafer carrying tool is removed. In Step 408, the carried wafer can be loaded or placed precisely at the predetermined location of the wafer table as the position of the wafer carried by the wafer holder is calibrated and the bias issues arising from the shifted position of the wafer carried by the wafer holder are solved. Hence, the loaded wafer can be properly held by the wafer chuck of the wafer table, thus avoiding the coordination bias or position shifting between the wafer and the wafer table. Taking the round wafer table as an example, when the wafer is placed at the prearranged position on the wafer table without position deviation, the wafer and the wafer table are concentric. In Step 410, the spin-coating process is performed to the wafer accurately positioned on the wafer table of the next processing unit. As the wafer is placed at the prearranged position on the wafer table without position deviation, the wafer can be processed properly and the coating of the wafer is completed with the symmetric (uniform) cut width.

Although in the above embodiment(s), the wafer holder of the wafer carrying tool carries the wafer to a wafer table, the wafer holder or the wafer carrying tool may be equipped with any compatible processing system, apparatus or platform, and the applicable processes are not limited to the spin-coating process but may be applicable to other semiconductor manufacturing processes, such as photolithography, development, thermal treatment, baking . . . etc.

From the above descriptions, the wafer carried by the wafer holder or the wafer carrying tool can be centered and correctly positioned by the wafer centering unit and the carried wafer can be accurately loaded to the wafer table without off-axis or position-shifting problems, so that the control of positioning accuracy is enhanced and the positioning asymmetric issues is alleviated.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A semiconductor wafer carrying tool structure, comprising:
a support body;
a first shaft, connected with the support body;
an arm portion, connected with the first shaft, wherein one end of the arm portion is rotatably mounted to the support body through the first shaft;
a second shaft, connected with the arm portion; and
a wafer holder, for carrying a wafer, wherein the wafer holder is connected with the second shaft and is rotatably mounted on the other end of the arm portion through the second shaft,
wherein the wafer holder has a wafer centering unit comprising a plurality of pin cassettes and the plurality of pin cassettes is arranged on a frame portion of the wafer holder in diagonal positions, and each of the plurality of pin cassettes individually includes a retractable pin.

2. The structure of claim 1, wherein the plurality of pin cassettes arranged on the frame portion defines a spacing with a first diameter, and the first diameter is larger than a second diameter of the wafer.

3. The structure of claim 2, wherein when the wafer centering unit is in operation, the retractable pins are jutted out of the plurality of pin cassettes at the same time and each retractable pin is protruded out of the plurality of pin cassettes with a distance M, and the distance M is equivalent to a half of the difference between the first diameter and the second diameter.

4. The structure of claim 3, wherein when the wafer centering unit is not in operation, the retractable pins are located within the plurality of pin cassettes.

5. The structure of claim 1, wherein the plurality of pin cassettes includes four pin cassettes.

6. The structure of claim 1, wherein the wafer holder further comprises a plurality of support pins for supporting the wafer carried by the wafer holder, wherein the plurality of support pins is arranged on the frame portion of the wafer holder in diagonal positions, but the plurality of support pins is separate from the plurality of pin cassettes.

7. The structure of claim 6, wherein the plurality of support pins includes four support pins.

8. The structure of claim 1, wherein the wafer holder rotates about the first shaft, while the arm portion rotates about second shaft.

9. The structure of claim 1, wherein the first shaft and the second shaft are driven by a motor coupling to the support body.

10. A wafer holder, for carrying a wafer, comprising:
a frame portion;
a wafer centering unit comprising a plurality of pin cassettes, wherein the plurality of pin cassettes is arranged on the frame portion in diagonal positions, and each of the plurality of pin cassettes individually includes a retractable pin; and
a plurality of support pins for supporting the wafer carried by the wafer holder, wherein the plurality of support pins is arranged on the frame portion in diagonal positions and contacts with an edge of the wafer when supporting the wafer, and the plurality of support pins is separate from the plurality of pin cassettes.

11. The wafer holder of claim 10, wherein the plurality of pin cassettes arranged on the frame portion defines a spacing with a first diameter, and the first diameter is larger than a second diameter of the wafer.

12. The wafer holder of claim 11, wherein when the wafer centering unit is in operation, the retractable pins are jutted out of the plurality of pin cassettes at the same time and each retractable pin is protruded out of the plurality of pin cassettes with a distance M, and the distance M is equivalent to a half of the difference between the first diameter and the second diameter.

13. The wafer holder of claim 12, wherein when the wafer centering unit is not in operation, the retractable pins are located within the plurality of pin cassettes.

14. The wafer holder of claim 10, wherein the plurality of pin cassettes includes at least three pin cassettes.

15. The wafer holder of claim 10, wherein the plurality of support pins includes four support pins.
